(19) United States
(12) Patent Application Publication
(10) Pub. No.: US 2005/0017375 A1
(43) Pub. Date: Jan. 27, 2005

(54) Ball grid array package substrate and method for manufacturing the same

(75) Inventors: Shun-Fu Ko, Kaohsiung (TW); Yi-Chuan Ding, Kaohsiung (TW)

Correspondence Address: TROXELL LAW OFFICE PLLC, SUITE 1404, 5205 LEESBURG PIKE, FALLS CHURCH, VA, 22041, US

(73) Assignee: Advanced Semiconductor Engineering, Inc.

(21) Appl. No.: 10/885,623

(22) Filed: Jul. 8, 2004

(30) Foreign Application Priority Data
Jul. 10, 2003 (TW) 092118923

(51) Int. Cl. H01L 21/48; H01L 23/52

(52) U.S. Cl. 257/782; 257/783; 438/118; 257/786; 438/612

(57) ABSTRACT

A ball grid array package substrate includes a substrate body having a surface. A least a ball pad and a solder mask are formed on the surface of the substrate body. The solder mask has an opening corresponding to the ball pads to enable the ball pad to have an exposed surface out of the opening of the solder mask. A patterned reinforcing metal layer is formed on the exposed surface of ball pads along a sidewall of the opening of the solder mask so that the sidewall of the opening will not directly contact the solder balls. Solder balls can be reflowed on the ball pads and the patterned reinforcing metal layers to increase jointing area and improve the shear strength of the solder balls.

### FIELD OF THE INVENTION

The present invention relates to a substrate for semiconductor packages, particularly to a substrate for ball grid array (BGA) packages.

### BACKGROUND OF THE INVENTION

Conventionally substrates for ball grid array packages are generally utilized for carrying semiconductor chips. The substrate has a plurality of ball pads for mounting a plurality of solder balls as outer electrical connections. However, when the ball grid array package is in operation, thermal stress will occur causing extra shear stress between solder balls and ball pads of the substrate. A conventional substrate utilized for packaging semiconductor chips is disclosed in R.O.C. Taiwan Patent No. 491,410 entitled “Substrate for packaging semiconductor chip and packaging structure formed from the same”. The substrate is used for a ball grid array package with conductive traces inside for electrically connecting a chip and with a plurality of ball pads for mounting solder balls for electrically connecting to a PCB. Normally, solder balls are mounted on the exposed flat surface of the ball pads which are limited by solder mask openings on the substrate, so that the jointing area on the ball pads for mounting solder balls is relatively small. Therefore, the shear strength between solder balls and ball pads are weakened. When thermal stress is occurred due to the operations of a semiconductor package, the interface between solder balls and the, ball pads may be broken or even failed.

### SUMMARY

The main object of the present invention is to provide a ball grid array package substrate. A patterned reinforcing metal layer is formed on the ball pads (SMD pads) along a sidewall of the solder mask opening on the substrate. Solder balls can be mounted on the ball pads of the substrate with larger jointing area to improve the shear strength of the solder balls.

The secondary object of the present invention is to provide a ball grid array package substrate. A patterned reinforcing metal layer is formed on the ball pads of the substrate with central regions of the ball pads exposed. When solder balls are mounted on the exposed central regions of the ball pads and inside the patterned reinforcing metal layer, the solder mask will not affect the placement of the solder balls due to the patterned reinforcing metal layer, so that the shear strength of solder ball can be improved.

The third object of the present invention is to provide a manufacturing method of the ball grid array package substrate. A masking material is applied on the ball pads of a substrate body to partially cover the exposed surface of the ball pads, then a plurality of patterned reinforcing metal layers are formed on the ball pads along sidewalls of the opening of the solder mask without covering the central regions of the ball pads. Solder balls can be placed on the ball pads and inside the reinforcing metal layer for improving the shear strength of the solder balls.

According to the present invention, a ball grid array package substrate comprises a substrate body having a surface for mounting solder balls. At least a ball pad and a solder mask are formed on the surface of the substrate body. The solder mask has at least an opening partially exposing the ball pad. A patterned reinforcing metal layer is formed on the exposed surface of the ball pad along a sidewall of the opening of the solder mask. It is better that the patterned reinforcing metal layer expose the central region of the exposed surface of the ball pad to increase the jointing area of the solder balls on the ball grid array package substrate to improve the shear strength of the solder ball.

According to the present invention, a manufacturing method of the ball grid array package substrate is also disclosed. A substrate body having at least a ball pad on the surface is provided. Then a solder mask is applied on the surface of the substrate body. The solder mask has a plurality of openings partially exposing the ball pads. Then a masking material is applied on the exposed surface of the ball pads to cover parts of the exposed surface, such as the central region of the exposed surface. The masking material may be a dry film applied to the surface of the substrate which goes through exposure and development processes. Thereafter, a patterned reinforcing metal layer is formed on the ball pads along a sidewall of the opening of the solder mask by means of electrolytic plating, electroless plating or sputtering. Preferably, the patterned reinforcing metal layer is formed on the ball pads in accordance with the shape of exposed surface of the ball pads which is uncovered by the masking material. Finally, the masking material is removed to expose the central region of the ball pads inside the patterned reinforcing metal layer. It is better that a Ni/Au layer is formed over the ball pad and the patterned reinforcing metal layer by means of electroplating, so that the ball pads and the patterned reinforcing metal layer can be protected from oxidization during packaging processes. Moreover, the Ni/Au layer can wet the ball pads to increase the jointing area of the solder balls on the ball grid array package substrate to improve the shear strength of the solder balls.

### DESCRIPTION OF THE DRAWINGS

FIG. 1 is a cross-sectional view of a ball grid array package substrate in accordance with the embodiment of the present invention.

FIG. 2A˜2E are the cross-sectional views of the substrate illustrating the manufacturing processes of the ball grid array package substrate in accordance with the embodiment of the present invention.

FIG. 3A˜3C are top views of the ball pad of the substrate with patterned reinforcing metal layer in various shapes in accordance with the present invention.

FIG. 4 is a cross-sectional view of a ball grid array package including the substrate in accordance with the embodiment of the present invention.

### DETAILED DESCRIPTION OF THE PRESENT INVENTION

Referring to the drawings attached, the present invention will be described by means of the embodiments below.

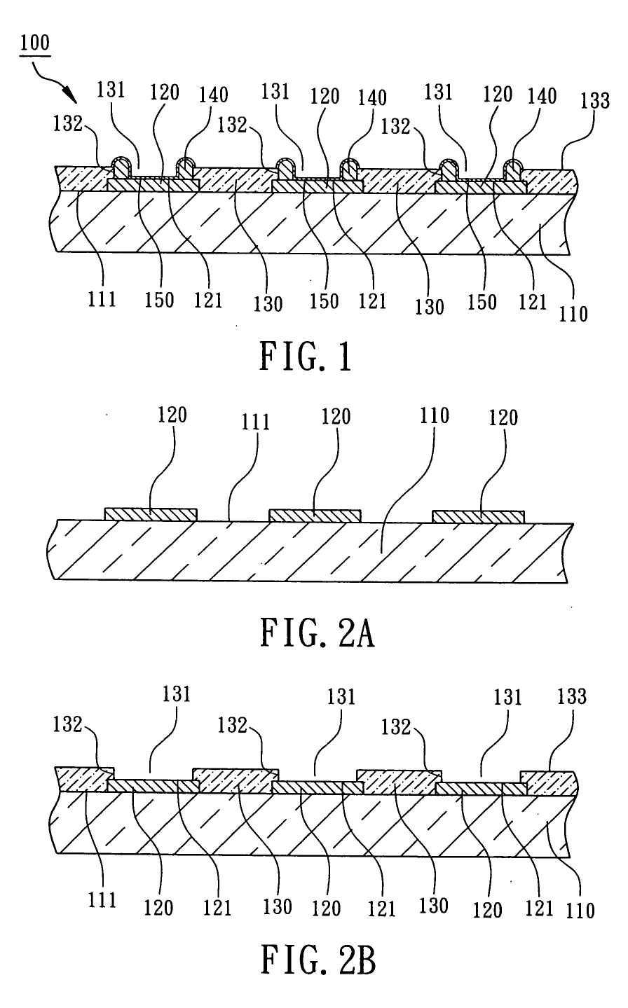

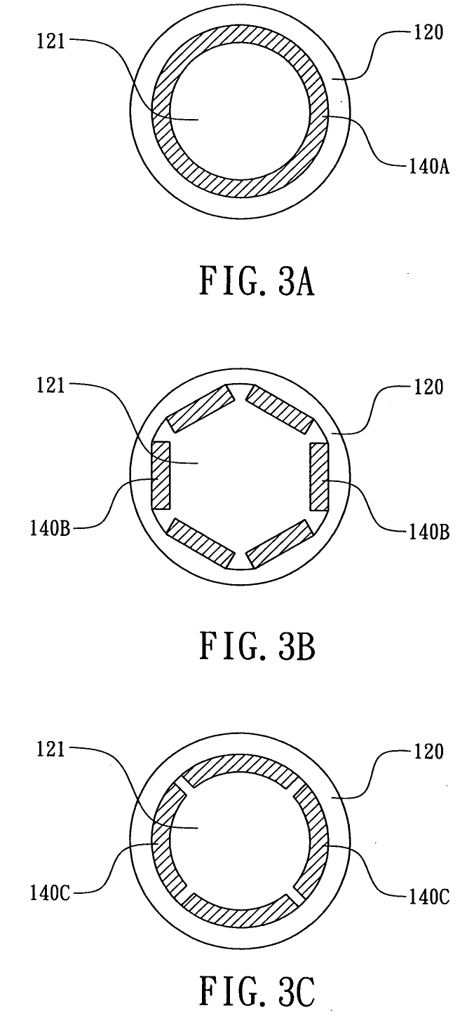

In accordance with the embodiment of the present invention, a ball grid array package substrate 100 is showed in FIG. 1. The substrate 100 comprises a substrate body 110, a plurality of ball pads 120, a solder mask 130 and a plurality of patterned reinforcing metal layers 140. The substrate body 110 has a surface 111 for SMT connection, the plurality of ball pads 120 and the solder mask 130 are formed on the surface 111 of the substrate body 110. The solder mask 130 has a plurality of openings 131 which partially expose the corresponding ball pads 120 so that each ball pad 120 has an exposed surface 121. Also each opening 131 can be circle or square in shape and has at least a sidewall 132. The patterned reinforcing metal layers 140 are formed on the corresponding ball pads 120 along the sidewalls 132 of the openings 131 of the solder mask 130. Preferably, the patterned reinforcing metal layers 140 tightly contact the sidewalls 132 of the solder mask 130. The patterned reinforcing metal layers 140 can be selected from the group of the patterned reinforcing metal layers 140A, 140B, 140C to be circle, strip, arc or discontinuous ring in various shapes as shown in FIG. 3A,3B,3C. In this embodiment, the patterned reinforcing metal layers 140 are made of copper, nickel or its alloy and expose the central regions of the exposed surfaces 121. In this embodiment, each opening 131 of the solder mask 130 is smaller than the corresponding ball pad 120 in dimension so that the ball pads 120 can be solder-mask-defined pad (SMD pad). Preferably the patterned reinforcing metal layers 140 are protruded from the outer surface 133 of the solder mask 130 and completely cover the sidewalls 132 of the openings 131 of the solder mask 130. In this embodiment, the patterned reinforcing metal layers 140 further partially cover the outer surface 133 of the solder mask 130 around the openings 131. Therefore, the patterned reinforcing metal layers 140 and the ball pads 120 provide a non-planar surfaces for mounting solder balls, and the sidewalls 132 of the openings 131 of the solder mask 130 will not affect the solder balls in a ball grid array package. Therefore, the shear strength of the solder balls can be improved. A Ni/Au layer or a pre-solder material is formed to cover the ball pads 120 and the patterned reinforcing metal layers 140 in order to protect the ball pads 120 from oxidization and improve wettability of the solder balls.

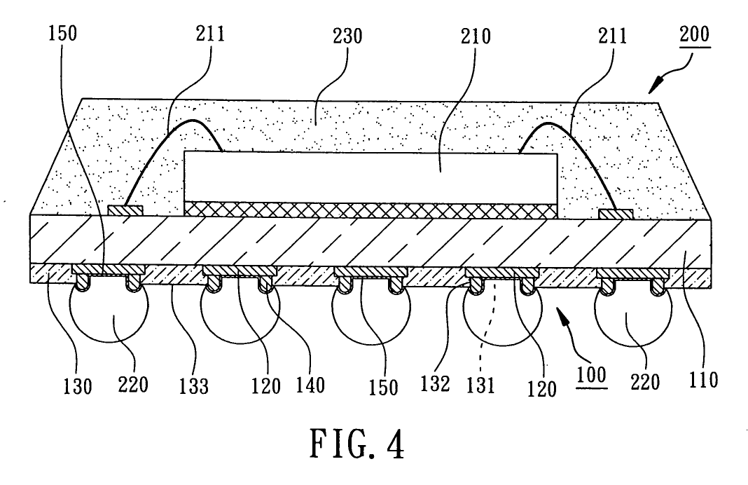

The patterned reinforcing metal layers 140 must be made from a material different from the solder ball 220 and have a melting point higher than the melting point of the solder balls 220. As a result, the patterned reinforcing metal layers 140 have enough hardness and formed along the sidewalls 132 of the openings 131 of the solder mask 130 during reflowing the solder balls 220. Referring to FIG. 4, since the sidewalls 132 of the solder mask 130 do not directly contact the solder ball 220, the solder balls 220 can strongly bonded to the ball pads 120 and the patterned reinforcing metal layers 140 to have an excellent shear strength.

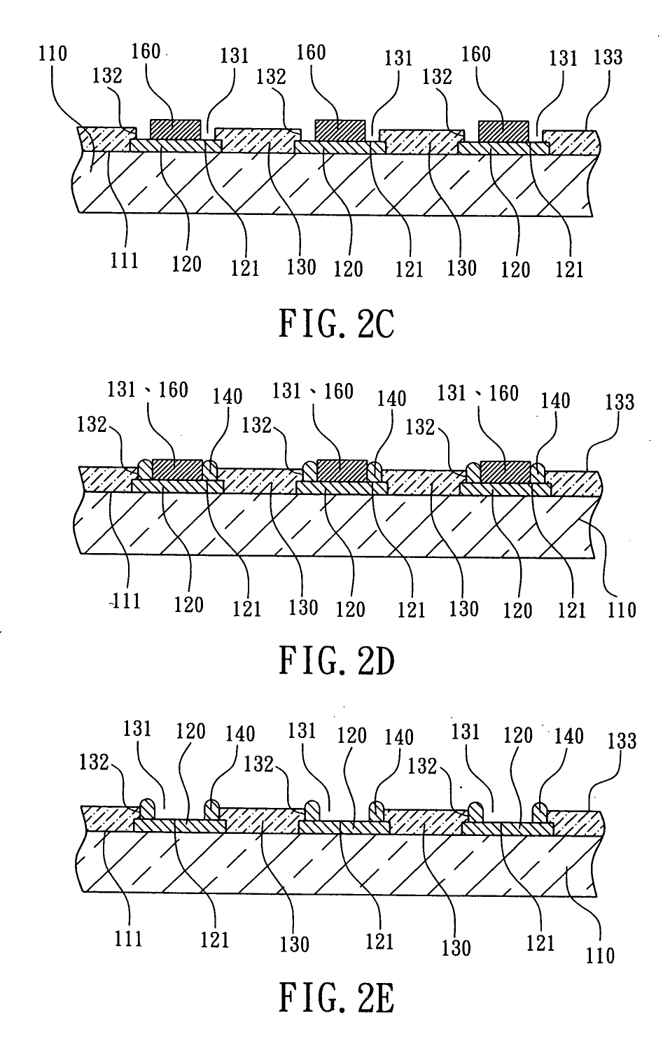

In order to illustrate the forming process of the foregoing patterned reinforcing metal layers 140, a manufacturing method of the foregoing ball grid array package substrate 100 according to the present invention is described as follows. Referring to FIG. 2A, a substrate body 110 having a plurality of ball pads 120 on a surface 111 is initially provided. Then referring to FIG. 2B, a solder mask 130 is applied on the surface 111 of the substrate body 110 by printing or curtain coating technique. By using exposure and development processes, the solder mask 130 has a plurality of openings 131 to expose the corresponding ball pads 120. Each ball pad 120 has an exposed surface 121 and each opening 131 has at least a sidewall 132. Then referring to FIG. 2C, a plurality of photoresist masking materials 160 are formed on the ball pads to cover the central regions of the exposed surface 121 of the ball pads 120. Periphery of the exposed surfaces 121 and the sidewalls 132 of the solder mask 130 are exposed out of the masking materials 160. The masking materials 160 can be formed by means of forming a dry film on the surface 111 of the substrate body 110, then exposing, developing and cleaning. Preferably, the masking materials 160 are higher than the outer surface 133 of the solder mask 130. Further referring to FIG. 2D, by using plating, electroless plating or sputtering technique, a plurality of patterned reinforcing metal layers 140 are formed on the ball pads 120 between the sidewalls 132 of the openings 131 and the masking materials 160. It is preferable that the patterned reinforcing metal layers 140 are formed on the exposed surface 121 of the ball pads 120 and expose the central regions of the exposed surface 121. The masking materials 160 are higher than the solder mask 130 which will make the patterned reinforcing metal layers 140 be slightly protruded from the solder mask 130. Preferably, the patterned reinforcing metal layers 140 completely cover the sidewalls 132 of the openings 131 of the solder mask 130. Finally referring to FIG. 2E, the masking materials 160 are removed to expose the central regions of exposed surface 121 of the ball pads 120 which are uncovered by the patterned reinforcing metal layers 140. It is better that a Ni/Au layer 150 are formed by means of electroplating technique to cover the central regions of the ball pads 120 and the patterned reinforcing metal layers 140 in order to protect the ball pads 120 from oxidization and improve wettability of the ball pads 120, as showed in FIG. 1.

Referring to FIG. 4, a ball grid array package 200 using the foregoing ball grid array package substrate 100 comprises the foregoing substrate 100, a chip 210 and a plurality of solder balls 220. The chip 210 is attached to the ball grid array package substrate 100 and electrically connected to the substrate 100 through the electrically connecting components, such as the bonding wires 211 or bumps. It is preferable that a molding compound 230 is formed on the substrate 100 to seal the chip 210 and the bonding wires 211. The solder balls 220 are mounted on the ball pads 120 and the patterned reinforcing metal layers 140. The patterned reinforcing metal layers 140 provide a non-planar and larger jointing area for solder balls 220. The solder balls 220 will not directly contact the sidewalls 132 of the openings 131 of the solder mask 130 to eliminate poor adhesion of the solder mask 130 against the solder ball 220.

The above description of embodiments of this invention is intended to be illustrated and not limited. Other embodiments of this invention will be obvious to those skilled in the art in view of the above disclosure.

1. A substrate for ball grid array package comprising:
a substrate body having a surface;
at least a ball pad formed on the surface of the substrate body;
a solder mask formed on the surface of the substrate body, wherein the solder mask has at least an opening partially exposing the ball pad; and
a patterned reinforcing metal layer formed on the ball pad along a sidewall of the opening of the solder mask.

2. The substrate in accordance with claim 1, wherein the ball pad has a central region exposed out of the patterned reinforcing metal layer and the solder mask.

3. The substrate in accordance with claim 1, further comprising a Ni/Au layer formed over the ball pad and the patterned reinforcing metal layer.

4. The substrate in accordance with claim 1, wherein the patterned reinforcing metal layer partially covers the solder mask.

5. The substrate in accordance with claim 1, wherein the shape of the patterned reinforcing metal layer is circle, strip, arc or discontinuous ring.

6. The substrate in accordance with claim 1, wherein the patterned reinforcing metal layer is protruded from the solder mask.

7. The substrate in accordance with claim 1, wherein the patterned reinforcing metal layer completely covers the sidewall of the opening of the solder mask.

8. The substrate in accordance with claim 1, wherein the patterned reinforcing metal layer is made of copper, nickel or alloys thereof.

9. A ball grid array package comprising:
a package substrate comprising:
a substrate body having a surface;
a plurality of ball pads formed on the surface of the substrate body;
a solder mask formed on the surface of the substrate body, wherein the solder mask has
a plurality of openings partially exposing the ball pads;
a patterned reinforcing metal layer formed on the exposed ball pads along a sidewall of the openings of the solder mask;
a chip attached to the package substrate; and
a plurality of solder balls mounted to the ball pads.

10. The package in accordance with claim 9, wherein each ball pad has a central region exposed out of the patterned reinforcing metal layer and the solder mask for mounting solder balls.

11. The package in accordance with claim 9, further comprising a Ni/Au layer formed over the ball pad and the patterned reinforcing metal layer.

12. The package in accordance with claim 9, wherein the patterned reinforcing metal layer partially covers the upper surface of the solder mask around the opening.

13. The package in accordance with claim 9, wherein the shape of the patterned reinforcing metal layer is circle, strip, arc, or discontinuous ring.

14. The package in accordance with claim 9, wherein the patterned reinforcing metal layer is protruded from the solder mask.

15. The package in accordance with claim 9, wherein the patterned reinforcing metal layer completely covers the sidewalls of the openings of the solder mask.

16. The package in accordance with claim 9, wherein the patterned reinforcing metal layer is made of copper, nickel or alloys thereof.

17. The package in accordance with claim 9, wherein the melting point of the patterned reinforcing metal layer is higher than that of the solder ball.

18. A method for manufacturing a ball grid array package substrate comprising the steps of:
providing a substrate body having a surface, at least a ball pad being formed on the surface;
forming a solder mask on the surface of the substrate body, the solder mask having at least an opening partially exposing the ball pad;
forming at least a masking material, the masking material covering the exposed ball pad in a pattern and exposing an sidewall of the opening;
forming a patterned reinforcing metal layer on the exposed ball pad along the sidewall of the opening of the solder mask; and
removing the masking material.

19. The method in accordance with claim 18, wherein the ball pad has a central region exposed out of the patterned reinforcing metal layer and the solder mask.

20. The method in accordance with claim 18, further comprising: forming a Ni/Au layer over the ball pad and the patterned reinforcing metal layer.

21. The method in accordance with claim 18, wherein the patterned reinforcing metal layer partially covers the upper surface of the solder mask around the opening.

22. The method in accordance with claim 18, wherein the shape of the patterned reinforcing metal layer is circle, strip, arc or discontinuous ring.

23. The method in accordance with claim 18, wherein the patterned reinforcing metal layer is protruded from the solder mask.

24. The method in accordance with claim 18, wherein the patterned reinforcing metal layer completely covers the sidewall of the opening of the solder mask.

25. The method in accordance with claim 18, wherein the patterned reinforcing metal layer is made of copper, nickel or alloys thereof.

26. The method in accordance with claim 18, wherein the masking material is made from a dry film.
